(19) United States
(12) Patent Application Publication
(10) Pub. No.: US 2023/0183272 A1
(43) Pub. Date: Jun. 15, 2023

(54) COMPOSITIONS AND METHODS USING SAME FOR SILICON CONTAINING FILMS

(71) Applicant: VERSUM MATERIALS US, LLC, TEMPE, AZ (US)

(72) Inventors: XINJIAN LEI, VISTA, CA (US); MATTHEW R. MCDONALD, LAGUNA NIGUEL, CA (US); MANCHAO XIAO, SAN DIEGO, CA (US); MING LI, SAN MARCOS, CA (US); MEILIANG WANG, SAN MARCOS, CA (US)

(21) Appl. No.: 18/152,116

(22) Filed: Jan. 9, 2023

Related U.S. Application Data
(62) Division of application No. 16/779,798, filed on Feb. 3, 2020, now abandoned.
(60) Provisional application No. 62/800,085, filed on Feb. 1, 2019.

(51) Int. Cl. C07F 7/02; C23C 16/455; C23C 16/34; C23C 16/44; C23C 16/50; C23C 16/36

(52) U.S. Cl. CPC C07F 7/025; C23C 16/36; C23C 16/50; C23C 16/345; C23C 16/4408; C23C 16/45536; C23C 16/45553

(57) ABSTRACT

Described herein are precursors and methods for forming silicon-containing films. In one aspect, there is provided a precursor of Formula I:

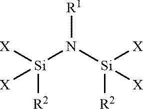

as described herein.

### CROSS REFERENCE TO RELATED APPLICATIONS

This application is a division of U.S. Application No. 16/779,798, filed Feb. 3, 2020, which claims priority to U.S. Provisional Application 62/800,085 filed on Feb. 1, 2019. The entire contents of both applications are incorporated herein by reference thereto for all allowable purposes.

### FIELD OF THE INVENTION

Described herein is a composition and method for the fabrication of an electronic device. More specifically, described herein are compounds, and compositions and methods comprising the same, for the deposition of a low dielectric constant (< 4.0) and high oxygen ash resistant silicon-containing film such as, without limitation, amorphous silicon, crystalline silicon, silicon oxide, silicon oxycarbide, silicon nitride, silicon oxynitride, and silicon oxycarbonitride.

### BACKGROUND OF THE INVENTION

There is a need in the art to provide a composition and method using the same for depositing high carbon content (e.g., a carbon content of about 10 atomic % or greater as measured by X-ray photoelectron spectroscopy (XPS)) doped silicon-containing films for certain applications within the electronics industry.

U.S. Pat. No. 8,575,033 describes methods for deposition of silicon carbide films on a substrate surface. The methods include the use of vapor phase carbosilane precursors and may employ plasma enhanced atomic layer deposition processes.

U.S. Publ. No. 2013/022496 teaches a method of forming a dielectric film having Si-C bonds on a semiconductor substrate by atomic layer deposition (ALD). The method includes: (i) adsorbing a precursor on a surface of a substrate; (ii) reacting the adsorbed precursor and a reactant gas on the surface; and (iii) repeating steps (i) and (ii) to form a dielectric film having at least Si—C bonds on the substrate.

PCT Appl. No. WO14134476A1 describes methods for the deposition of films comprising SiCN and SIOCN. Certain methods involve exposing a substrate surface to a first and second precursor, the first precursor having a formula (X_{y}H_{3-y}Si)zCH_{4-z}, (X_{y}H₃₋ _{y}Si)(CH₂)(SiXₚH₂₋ₚ)(CH₂)(SiX_{y}H_{3-y}), or (X_{y}H_{3-y}Si)(CH₂)ₙ(SiX_{y}H_{3-y}), wherein X is a halogen, y has a value of between 1 and 3, and z has a value of between 1 and 3, p has a value of between 0 and 2, and n has a value between 2 and 5, and the second precursor comprising a reducing amine. Certain methods also comprise exposure of the substrate surface to an oxygen source to provide a film comprising carbon doped silicon oxide.

Hirose, Y., Mizuno, K., Mizuno, N., Okubo, S., Okubo, S., Yanagida, K. and Yanagita, K. (2014)) “Method of manufacturing semiconductor device, substrate processing apparatus, and recording medium,” U.S. Appl.No. 2014287596A, describes a method of manufacturing a semiconductor device including forming a thin film containing silicon, oxygen and carbon on a substrate by performing a cycle a predetermined number of times, the cycle including: supplying a precursor gas containing silicon, carbon and a halogen element and having an Si—C bonding, and a first catalytic gas to the substrate; and supplying an oxidizing gas and a second catalytic gas to the substrate.

Hirose, Y., Mizuno, N., Yanagita, K. and Okubo, S. (2014)) “Method of manufacturing semiconductor device, substrate processing apparatus, and recording medium,” U.S. Pat. No. 9,343,290 B, describes a method of manufacturing a semiconductor device that includes forming an oxide film on a substrate by performing a cycle a predetermined number of times. The cycle includes supplying a precursor gas to the substrate; and supplying an ozone gas to the substrate. In the act of supplying the precursor gas, the precursor gas is supplied to the substrate in a state where a catalytic gas is not supplied to the substrate, and in the act of supplying the ozone gas, the ozone gas is supplied to the substrate in a state by which an amine-based catalytic gas is supplied to the substrate.

U.S. Pat. No. 9,349,586 B discloses a thin film having a desirable etching resistance and a low dielectric constant.

U.S. Publ. No. 2015/0044881 A describes a method by which a a film containing carbon added at a high concentration is formed with high controllability. A method of manufacturing a semiconductor device includes forming a film containing silicon, carbon and a predetermined element on a substrate by performing a cycle a predetermined number of times. The predetermined element is one of nitrogen and oxygen. The cycle includes supplying a precursor gas containing at least two silicon atoms per one mol., carbon and a halogen element and having a Si—C bonding to the substrate, and supplying a modifying gas containing the predetermined element to the substrate.

The reference entitled “Highly Stable Ultrathin Carbosiloxane Films by Molecular Layer Deposition”, Han, Z. et al., Journal of Physical Chemistry C, 2013, 117, 19967, teaches growing a carbosiloxane film using 1,2-bis[(dimethylamino)dimethylsilyl]ethane and ozone. Thermal stability shows film is stable at up to 40° C. with little thickness loss at 60° C.

Liu et al, Jpn. J. Appl. Phys., 1999, Vol. 38, 3482-3486, teaches H₂ plasma use on polysilsesquioxane deposited with spin-on technology. The H₂ plasma provides a film having a stable dielectric constant and improves film thermal stability and experiences less damage during an O₂ ash (plasma) treatment.

Kim et al, Journal of the Korean Physical Society, 2002, Vol. 40, 94, teaches that a H₂ plasma treatment on PECVD SiOC film improves leakage current density (4-5 orders of magnitude) while increasing the dielectric constant from 2.2 to 2.5. The SiOC film after the H₂ plasma experiences less damage during an O₂ ashing process.

Posseme et al, Solid State Phenomena, 2005, Vol. 103-104, 337, teaches a different H₂ / inert plasma treatment on a SiOC PECVD film. The dielectric constant k does not improve after an H₂ plasma treatment, suggesting no bulk modification.

The disclosure of the previously identified patents, patent applications and publications is hereby incorporated by reference.

### BRIEF SUMMARY OF THE INVENTION

Described herein are silicon precursors comprising a silazane compound having one organoamino group connected to two SiR²X₂ groups, compositions comprising the same, and methods using the same for forming films comprising silicon, such as, but not limited to, silicon oxide, carbon doped silicon oxide, silicon nitride, silicon oxynitride, silicon carbide, silicon carbonitride, and combinations thereof onto at least a portion of a substrate. In addition, described herein is a composition comprising a silazane that is substantially free of at least one species selected from organoamines, higher molecular weight species, and trace metals. The composition may further comprise a solvent. Also disclosed herein are the methods to form films or coatings comprising silicon on an object to be processed, such as a semiconductor wafer. In one embodiment of the method described herein, a film comprising silicon and oxygen is deposited onto a substrate using a silazane precursor and an oxygen-containing source in a deposition chamber under conditions for generating a silicon oxide or carbon doped silicon oxide film on the substrate. In another embodiment of the method described herein, a film comprising silicon and nitrogen is deposited onto a substrate using a silazane precursor and a nitrogen containing precursor in a deposition chamber under conditions for generating a silicon nitride film on the substrate. In a further embodiment, the silazane precursors described herein can also be used as a dopant for metal containing films, such as but not limited to, metal oxide films or metal nitride films. In the compositions and methods described herein, a silazane having the formula described herein is employed as at least one of the silicon containing precursors.

In one aspect, a silicon precursor described herein comprises at least one silazane precursor comprising only one organoamino group connected to two SiR²X₂ groups represented by the following Formula I below:

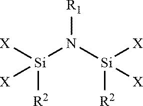

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a Cₛ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I.

In another aspect, there is provided a composition comprising: (a) a silicon precursor described herein comprises at least one silazane precursor comprising only one organoamino group connected to two SiR²X₂ groups represented by the following Formula I below:

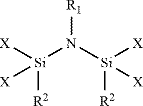

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and (b) at least one solvent. In certain embodiments of the composition described herein, exemplary solvents include, without limitation, ether, tertiary amine, alkyl hydrocarbon, aromatic hydrocarbon, siloxanes, tertiary aminoether, and combinations thereof. In certain embodiments, the difference between the boiling point of the silicon compounds and the boiling point of the solvent is 40° C. or less, less than about 30° C. and in some cases less than about 20° C., and most preferably less than 10° C.

In another aspect, there is provided a method for forming a silicon-containing film on at least one surface of a substrate comprising providing the at least one surface of the substrate in a reaction chamber; and forming the silicon-containing film on the at least one surface by a deposition process chosen from a chemical vapor deposition process and an atomic layer deposition process using at least one silazane precursor comprising only one organoamino group connected to two SiR2X2 groups represented by the following Formula I below:

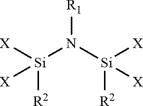

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I.

In another aspect, there is provided a method of forming a silicon oxide or carbon doped silicon oxide film via an atomic layer deposition process or ALD-like process, the method comprising the steps of:
a. providing a substrate in a reactor;
b. introducing into the reactor at least one silazane precursor comprising only one organoamino group connected to two SiR²X₂ groups represented by the following Formula I below:

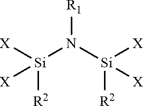

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I;
c. purging the reactor with a purge gas;
d. introducing an oxygen-containing source into the reactor; and
e. purging the reactor with a purge gas; wherein steps b through e are repeated until a desired thickness of the film is obtained.

In a further aspect, there is provided a method of forming a film selected from a silicon oxide film and a carbon doped silicon oxide film onto at least a surface of a substrate using a CVD process comprising:
a. providing a substrate in a reactor;
b. introducing into the reactor at least one silazane precursor comprising only one organoamino group connected to two SiR²X₂ groups represented by the following Formula I below:

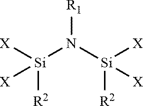

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and
c. providing an oxygen-containing source to deposit the film onto the at least one surface. In certain embodiments, R¹ and R² are the same. In some other embodiments, R¹ and Rare different

In another aspect, there is provided a method of forming a silicon nitride film via an atomic layer deposition process, the method comprising the steps of:
a. providing a substrate in a reactor;
b. introducing into the reactor an at least one silazane precursor comprising only one organoamino group connected to two SiR²X₂ groups represented by the following Formula I below:

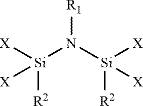

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I;
c. purging the reactor with a purge gas;
d. introducing a nitrogen-containing source into the reactor;
e. purging the reactor with a purge gas; and wherein steps b through e are repeated until a desired thickness of the silicon nitride film is obtained. In certain embodiments, R¹ and R² are the same. In some other embodiments, R¹ and R² are different.

In a further aspect, there is provided a method of forming a silicon nitride film onto at least a surface of a substrate using a CVD process comprising:
a. providing a substrate in a reactor;
b. introducing into the reactor at least one silazane precursor comprising only one organoamino group connected to two SiR²X₂ groups represented by the following Formula I below:

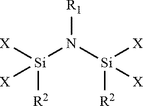

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and
c. providing a nitrogen-containing source wherein the at least one silazane precursor and the nitrogen-containing source react to deposit the film onto the at least one surface. In certain embodiments, R¹ and R² are the same. In some other embodiments, R¹ and R² are different.

In a further embodiment of the method described herein, there is provided a method of forming an amorphous or a crystalline silicon or silicon carbide film onto at least a surface of a substrate. In this embodiment, the method comprises:
a. placing one or more substrates into a reactor which is heated to one or more temperatures ranging from ambient temperature to about 1000° C.;
b. introducing at least one silazane precursor comprising only one organoamino group connected to two SiR²X₂ groups represented by the following Formula I below:

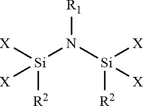

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀alkyl group, a linear or branched C₂ to C₆alkenyl group, a linear or branched C₃ to C₆alkynyl group, a C₃ to C₁₀ cyclic alkyl group, a C₂ to C₆dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and
c. providing a reducing agent source into the reactor to at least partially react with the at least one silazane precursor and deposit a silicon-containing film onto the one or more substrates. The reducing agent is selected from the group consisting of hydrogen, hydrogen plasma, and hydrogen chloride. In certain embodiments of the CVD method, the reactor is maintained at a pressure ranging from 10 mTorr to 760 Torr during the introducing step. The above steps define one cycle for the method described herein, and the cycle of steps can be repeated until the desired thickness of a film is obtained. In some embodiments, R¹ and Rare the same. In other embodiments, R¹ and Rare different.

In another aspect, there is provided a method of depositing an amorphous or a crystalline silicon or a silicon carbide film via an atomic layer deposition or cyclic chemical vapor deposition process, the method comprising the steps of:
a. providing a substrate in a reactor;
b. introducing into the reactor at least one silazane precursor comprising only one organoamino group connected to two SiR²X₂ groups represented by the following Formula I below:

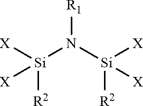

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I, wherein step b is repeated until a desired thickness of the film is obtained. In certain embodiments, the thickness of the film is 1 Å or greater, or 1 to 10,000 Å, or 1 to 1000 Å, or 1 to 100 Å.

### DETAILED DESCRIPTION OF THE INVENTION

The silazane precursors described herein are used to form stoichiometric and non-stoichiometric silicon containing films such as, but not limited to, amorphous silicon, crystalline silicon, silicon oxide, silicon oxycarbide, silicon nitride, silicon oxynitride, and silicon oxycarbonitride. These precursors can also be used, for example, as dopants for metal containing films. The silazane precursors used in semi-conductor processes are typically high purity volatile liquid chemicals that are vaporized and delivered to a deposition chamber or reactor as a gas to deposit a silicon containing film via CVD or ALD processes for semiconductor devices. The selection of precursor materials for deposition depends upon the desired resultant silicon-containing material or film. For example, a precursor material may be chosen for its content of chemical elements, its stoichiometric ratios of the chemical elements, and/or the resultant silicon containing film or coating that are formed under CVD. The precursor material may also be chosen for various other characteristics such as cost, relatively low toxicity, handling characteristics, ability to maintain liquid phase at room temperature, volatility, molecular weight, and/or other considerations. In certain embodiments, the precursors described herein can be delivered to the reactor system by any number of means, preferably using a pressurizable stainless steel vessel fitted with the proper valves and fittings, to allow the delivery of liquid phase precursor to the deposition chamber or reactor.

The silazane precursors described herein exhibit a balance of reactivity and stability that makes them ideally suitable as CVD or ALD precursors in microelectronic device manufacturing processes. With regard to reactivity, the silazane in this invention has two SiRX₂ groups which helps react the silazane precursors with hydroxyl surface during ALD process. Certain precursors may have boiling points that are too high to be vaporized and delivered to the reactor to be deposited as a film on a substrate, so it is preferable to select smaller organoamino groups as well as smaller alkyl groups to provide precursors having boiling points of 250° C. or less, preferably boiling points of 200° C. or less. Having two or more organoamino groups, as disclosed in prior art, can increase the boiling point significantly; precursors having higher relative boiling points require that the delivery container and lines need to be heated at or above the boiling point of the precursor under a given vacuum to prevent condensation or particles from forming in the container, lines, or both. With regard to stability, other precursors may form silane (SiH₄) or disilane (Si₂H₆) as they degrade. Silane is pyrophoric at room temperature or it can spontaneously combust which presents safety and handling issues. Moreover, the formation of silane or disilane and other by-products decreases the purity level of the precursor and changes as small as 1-2% in chemical purity may be considered unacceptable for reliable semiconductor manufacture. In certain embodiments, the silazane precursors having Formula I described herein comprise 2% or less by weight, or 1% or less by weight, or 0.5% or less by weight of impurities (such as free organoamine, X-SiR²X₂ species, or higher molecular weight disproportionation products) after being stored for a time period of 6 months or greater, or one year or greater which is indicative of being shelf stable. In addition to the foregoing advantages, in certain embodiments, such as for depositing a silicon oxide or silicon nitride or silicon film using an ALD, ALD-like, PEALD, or CCVD deposition method, the silazane precursor described herein is able to deposit high density materials at relatively low deposition temperatures, e.g., 1000° C. or less, 800° C. or less, 700° C. or less, 500° C. or less, or 400° C. or less, 300° C. or less, 200° C. or less, 100° C. or less, or 50° C. or less.

In one embodiment, described herein is a composition for forming a silicon-containing film comprising: a silazane having Formula I described herein and a solvent(s). Without intending to be bound by any particular theory, it is believed that composition described herein may provide one or more advantages compared to exisistng silicon precursors such as hexachlorodisilane and dichlorosilane. These advantages include: better usage of the silazane in semiconductor processes, better stability over long term storage, cleaner evaporation by flash vaporization, and/or overall more stable direct liquid injection (DLI) chemical vapor deposition process. The weight percentage of the silazane in the composition can range from 1 to 99% with the balance being solvent(s) wherein the solvent(s) does not react with the silazane and has a boiling point similar to the silazane. With regard to the latter, the difference between the boiling points of the silazane and solvent(s) in the composition is 40° C. or less, more preferably 20° C. or less, or 10° C. or less.

In one aspect, there is provided at least one silazane precursor comprising only one organoamino group connected to two SiR²X₂ groups represented by the following Formula I below:

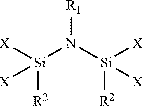

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I.

In the formulae and throughout the description, the term “alkyl” denotes a linear, or branched functional group having from 1 to 10 or 1 to 6 carbon atoms. Exemplary alkyl groups include, but are not limited to, methyl, ethyl, propyl, isopropyl, butyl, isobutyl, sec-butyl, tert-butyl, pentyl, iso-pentyl, tert-pentyl, hexyl, iso-hexyl, and neo-hexyl. In certain embodiments, the alkyl group may have one or more functional groups such as, but not limited to, an alkoxy group, a dialkylamino group or combinations thereof, attached thereto. In other embodiments, the alkyl group does not have one or more functional groups attached thereto.

In the formulae and throughout the description, the term “cyclic alkyl” denotes a cyclic functional group having from 3 to 10 or from 4 to 10 carbon atoms or from 5 to 10 carbon atoms. Exemplary cyclic alkyl groups include, but are not limited to, cyclobutyl, cyclopentyl, cyclohexyl, and cyclooctyl groups.

In the formulae and throughout the description, the term “aryl” denotes an aromatic cyclic functional group having from 5 to 12 carbon atoms or from 6 to 10 carbon atoms. Exemplary aryl groups include, but are not limited to, phenyl, benzyl, chlorobenzyl, tolyl, and o-xylyl.

In the formulae and throughout the description, the term “alkenyl group” denotes a group which has one or more carbon-carbon double bonds and has from 3 to 10 or from 3 to 6 or from 3 to 4 carbon atoms.

In the formulae and throughout the description, the term “alkynyl group” denotes a group which has one or more carbon-carbon triple bonds and has from 3 to 10 or from 3 to 6 or from 3 to 4 carbon atoms.

In the formulae and throughout the description, the term “organoamino group” denotes a group which has one alkyl group attached to a nitrogen atom and has from 1 to 10 or from 2 to 6 or from 2 to 4 carbon atoms. Exemplary organoamino groups include, but limited to, methylamino, ethylamino, normal-propylamine, iso-propylamino, normal-butylamino, iso-butylamino, sec-butylamino, tert-butylamino.

In the formulae and throughout the description, the term “dialkylamino group” denotes a group which has two alkyl groups attached to a nitrogen atom, wherein each alkyl group has, for example, from 1 to 10, from 2 to 6, or from 2 to 4 carbon atoms. Exemplary dialkylamino groups include, but limited to, dimethylamino, diethylamino, ethylmethylamino, di-normal-propylamine, di-iso-propylamino, di-normal-butylamino, di-iso-butylamino, di-sec-butylamino, di-tert-butylamino.

The term “electron withdrawing group” as used herein describes an atom or group thereof that acts to draw electrons away from the Si—N bond. Examples of suitable electron withdrawing groups or substituents include, but are not limited to, nitriles (CN). In certain embodiments, electron withdrawing substituent can be adjacent to or proximal to N in any one of Formula I. Further non-limiting examples of an electron withdrawing group includes F, Cl, Br, I, CN, NO₂, RSO, and/or RSO₂ wherein R can be a C₁ to C₁₀ alkyl group such as, but not limited to, a methyl group or another group.

In certain embodiments, one or more of the alkyl group, alkenyl group, alkynyl group, alkoxy group, dialkylamino group, aryl group, and/or electron withdrawing group in Formula I may be substituted or have one or more atoms or group of atoms substituted in place of, for example, a hydrogen atom. Exemplary substituents include, but are not limited to, oxygen, sulfur, halogen atoms (e.g., F, Cl, I, or Br), nitrogen, and phosphorous.

In certain embodiments, the at least one silazane precursor having Formula I has one or more substituents comprising oxygen or nitrogen atoms.

It is believed that the unique structures of the Formula I precursors described herein allow for deposition temperatures of 1000° C. or less, 700° C. or less, 500° C. or less, 400° C. or less, 300° C. or less, 200° C. or less, 100° C. or less, or 25° C. or less.

Table 1 lists examples of silicon precursors having one organoamino group connected to two SiR²X₂ groups according to Formula I.

TABLE 1

Silicon precursors having two SiR²X₂ groups

| | |
|---|---|
| 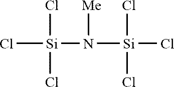 1,1,1,3,3,3-hexachloro-2-methyldisilazane | 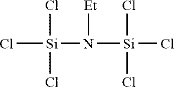 [SMILES: CCN([Si](Cl)(Cl)Cl)[Si](Cl)(Cl)Cl] 1,1,1,3,3,3-hexachloro-2-ethyldisilazane |
| 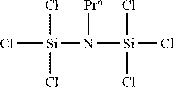 1,1,1,3,3,3-hexachloro-2-n-propyldisilazane | 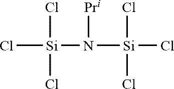 |
| | 1,1,1,3,3,3-hexachloro-2-iso-propyldisilazane |
| 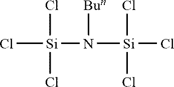 1,1,1,3,3,3-hexachloro-2-n-butyldisilazane | 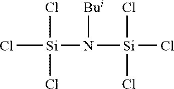 1,1,1,3,3,3-hexachloro-2-iso-butyldisilazane |
| 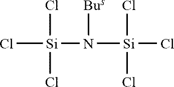 1,1,1,3,3,3-hexachloro-2-sec-butyldisilazane | 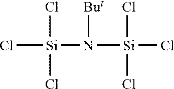 1,1,1,3,3,3-hexachloro-2-tert-butyldisilazane |
| 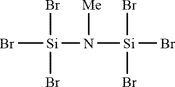 1,1,1,3,3,3-hexabromo-2-methyldisilazane | 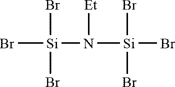 [SMILES: CCN([Si](Br)(Br)Br)[Si](Br)(Br)Br] 1,1,1,3,3,3-bromo-2-ethyldisilazane |
| 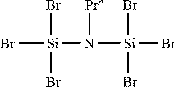 1,1,1,3,3,3-bromo-2-n-propyldisilazane | 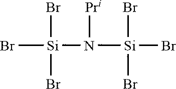 1,1,1,3,3,3-bromo-2-iso-propyldisilazane |
| 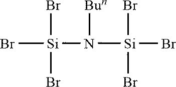 1,1,1,3,3,3-bromo-2-n-butyldisilazane | 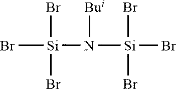 1,1,1,3,3,3-bromo-2-iso-butyldisilazane |
| 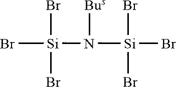 1,1,1,3,3,3-bromo-2-sec-butyldisilazane | 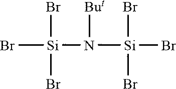 1,1,1,3,3,3-bromo-2-tert-butyldisilazane |
| 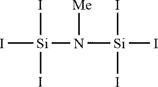 1,1,1,3,3,3-hexaiodo-2-methyldisilazane | 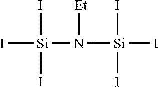 [SMILES: CCN([Si](I)(I)I)[Si](I)(I)I] 1,1,1,3,3,3-iodo-2-ethyldisilazane |
| 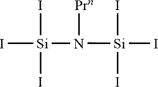 | 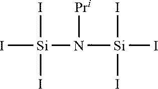 |
| 1,1,1,3,3,3-iodo-2-n-propyldisilazane | 1,1,1,3,3,3-iodo-2-iso-propyldisilazane |
| 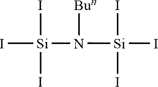 1,1,1,3,3,3-iodo-2-n-butyldisilazane | 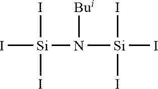 1,1,1,3,3,3-iodo-2-iso-butyldisilazane |
| 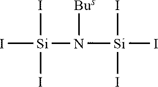 1,1,1,3,3,3-iodo-2-sec-butyl-disilazane | 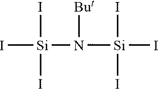 1,1,1,3,3,3-iodo-2-tert-butyl-disilazane |
| 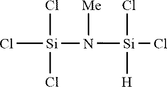 1,1,1,3,3-pentachloro-2-methyldisilazane | 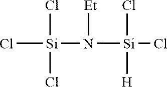 1,1,1,3,3-pentachloro-2-ethyldisilazane |
| 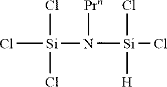 1,1,1,3,3-pentachloro-2-n-propyldisilazane | 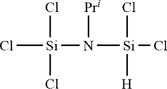 1,1,1,3,3-pentachloro-2-iso-propyldisilazane |
| 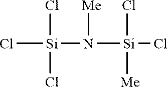 1,1,1,3,3-pentachloro-2-methyl-3-methyl-disilazane | 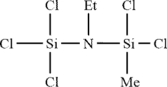 [SMILES: CCN([Si](C)(Cl)Cl)[Si](Cl)(Cl)Cl] 1,1,1,3,3-pentachloro-2-ethyl-3-methyldisilazane |
| 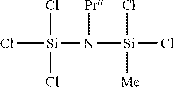 1,1,1,3,3-pentachloro-2-n-propyl-3-methyldisilazane | 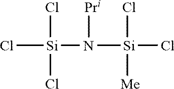 1,1,1,3,3-pentachloro-2-iso-propyl-3-methyldisilazane |
| 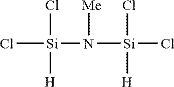 1,1,3,3-tetrachloro-2-methyldisilazane | 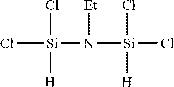 1,1,3,3-tetrachloro-2-ethyldisilazane |
| 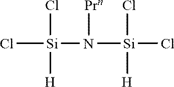 1,1,3,3-tetrachloro-2-n-propyldisilazane | 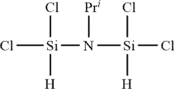 1,1,3,3-tetrachloro-2-iso-propyldisilazane |
| 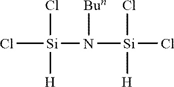 1,1,3,3-tetrachloro-2-n-butyldisilazane | 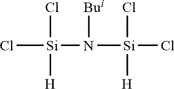 1,1,3,3-tetrachloro-2-iso-butyldisilazane |
| 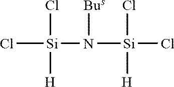 1,1,3,3-tetrachloro-2-sec-butyldisilazane | 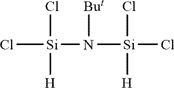 1,1,3,3-tetrachloro-2-tert-butyldisilazane |
| 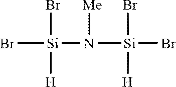 1,1,3,3-tetrabromo-2-methyldisilazane | 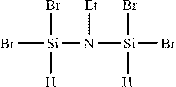 1,1,3,3-tetrabromo-2-ethyldisilazane |
| 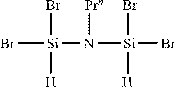 1,1,3,3-tetrabromo-2-n-propyldisilazane | 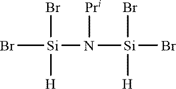 1,1,3,3-tetrabromo-2-iso-propyldisilazane |
| 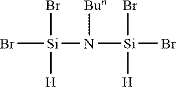 1,1,3,3-tetrabromo-2-n-butyldisilazane | 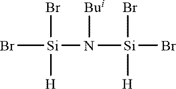 1,1,3,3-tetrabromo-2-iso-butyldisilazane |
| 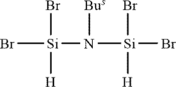 1,1,3,3-tetrabromo-2-sec-butyldisilazane | 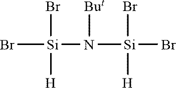 1,1,3,3-tetrachloro-2-tert-butyldisilazane |
| 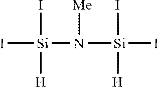 1,1,3,3-tetraiodo-2-methyldisilazane | 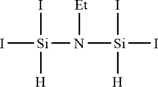 1,1,3,3-tetraiodo-2-ethyldisilazane |
| 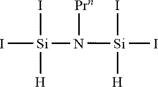 1,1,3,3-tetraiodo-2-n-propyldisilazane | 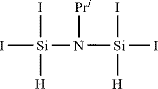 1,1,3,3-tetraiodo-2-iso-propyldisilazane |
| 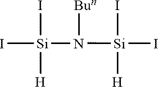 1,1,3,3-tetraiodo-2-n-butyldisilazane | 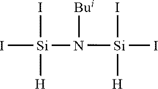 1,1,3,3-tetraiodo-2-iso-butyldisilazane |
| 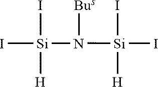 1,1,3,3-tetraiodo-2-sec-butyldisilazane | 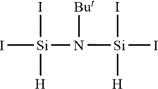 1,1,3,3-tetraiodo-2-tert-butyldisilazane |
| 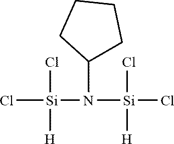 [SMILES: Cl[SiH](Cl)N(C1CCCC1)[SiH](Cl)Cl] 1,1,3,3-tetrachloro-2-cyclopentyldisilazane | 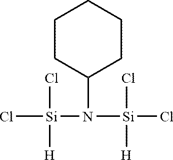 [SMILES: Cl[SiH](Cl)N(C1CCCCC1)[SiH](Cl)Cl] 1,1,3,3-tetrachloro-2-cyclohexyldisilazane |
| 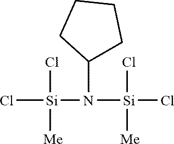 [SMILES: C[Si](Cl)(Cl)N(C1CCCC1)[Si](C)(Cl)Cl] 1,1,3,3-tetrachloro-1,3-dimethyl-2-cyclopentyl-2-cyclopentyldisilazane | 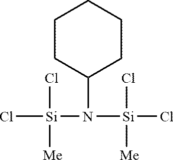 [SMILES: C[Si](Cl)(Cl)N(C1CCCCC1)[Si](C)(Cl)Cl] 1,1,3,3-tetrachloro-1,3-dimethyl-2-cyclohexyldisilazane |
| 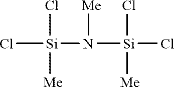 1,1,3,3-tetrachloro-1,3-dimethyl-2-methyldisilazane | 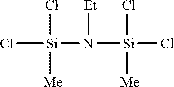 [SMILES: CCN([Si](C)(Cl)Cl)[Si](C)(Cl)Cl] 1,1,3,3-tetrachloro-1,3-dimethyl-tetrachloro-2-ethyldisilazane |
| 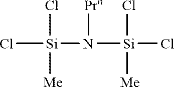 1,1 ,3,3-tetrachloro-1,3-dimethyl-2-n-propyldisilazane | 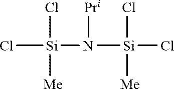 1,1,3,3-tetrachloro-1,3-dimethyl-2-iso-propyldisilazane |
| 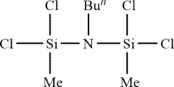 1,1 ,3,3-tetrachloro-1,3-dimethyl-2-n-butyldisilazane | 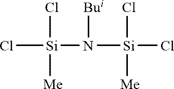 1,1,3,3-tetrachloro-1,3-dimethyl-2-iso-butyldisilazane |
| 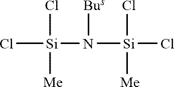 1,1,3,3-tetrachloro-1,3-dimethyl-2-sec-butyldisilazane | 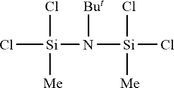 1,1 ,3,3-tetrachloro-1 ,3-dimethyl-2-tert-butyldisilazane |

The silazane precursors according to the present invention and compositions comprising the silazane precursors according to the present invention are preferably substantially free of organoamines or halide ions. As used herein, the term “substantially free” as it relates to halide ions (or halides) such as, for example, chlorides and fluorides, bromides, and iodides, means less than 5 ppm (by weight), preferably less than 3 ppm, and more preferably less than 1 ppm, and most preferably 0 ppm. As used herein, the term “free of” as it relates to halide ions or other impurities means 0 ppm. Chlorides are known to act as decomposition catalysts for silazanes. Significant levels of chloride in the final product can cause the silazane precursor to degrade. The gradual degradation of the silazane may directly impact the film deposition process making it difficult for the semiconductor manufacturer to meet film specifications. In addition, the shelf-life or stability is negatively impacted by the higher degradation rate of the silazane thereby making it difficult to guarantee a 1-2 year shelf-life. Therefore, the accelerated decomposition of the silazane presents safety and performance concerns related to the formation of these flammable and/or pyrophoric gaseous byproducts. Organoamines include, but not limited to, C₁ to C₁₀ organoamines, organodiamines. The silicon precursor compounds having Formulae I is preferably substantially free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “substantially free” as it relates to Li, Na, K, Mg, Ca, Al, Fe, Ni, Cr means less than 5 ppm (by weight), preferably less than 3 ppm, and more preferably less than 1 ppm, and most preferably 0.1 ppm as measured by ICP-MS. In some embodiments, the silicon precursor compounds having Formula A are free of metal ions such as, Li⁺, Na⁺, K⁺, Mg²⁺, Ca²⁺, Al³⁺, Fe²⁺, Fe²⁺, Fe³⁺, Ni²⁺, Cr³⁺. As used herein, the term “free of” metal impurities as it relates to Li, Na, K, Mg, Ca, Al, Fe, Ni, Cr, noble metal such as volatile Ru or Pt complexes from ruthenium or platinum catalysts used in the synthesis, means less than 1 ppm, preferably 0.1 ppm (by weight) as measured by ICP-MS or other analytical method for measuring metals.

The method used to form the silicon-containing films or coatings are deposition processes. Examples of suitable deposition processes for the method disclosed herein include, but are not limited to, cyclic CVD (CCVD), MOCVD (Metal Organic CVD), thermal chemical vapor deposition, plasma enhanced chemical vapor deposition (“PECVD”), high density PECVD, photon assisted CVD, plasma-photon assisted (“PPECVD”), cryogenic chemical vapor deposition, chemical assisted vapor deposition, hot-filament chemical vapor deposition, CVD of a liquid polymer precursor, deposition from supercritical fluids, and low energy CVD (LECVD). In certain embodiments, the metal containing films are deposited via atomic layer deposition (ALD), plasma enhanced ALD (PEALD) or plasma enhanced cyclic CVD (PECCVD) process. As used herein, the term “chemical vapor deposition processes” refers to any process wherein a substrate is exposed to one or more volatile precursors, which react and/or decompose on the substrate surface to produce the desired deposition. As used herein, the term “atomic layer deposition process” refers to a self-limiting (e.g., the amount of film material deposited in each reaction cycle is constant), sequential surface chemistry that deposits films of materials onto substrates of varying compositions. Although the precursors, reagents and sources used herein may be sometimes described as “gaseous”, it is understood that the precursors can be either liquid or solid which are transported with or without an inert gas into the reactor via direct vaporization, bubbling or sublimation. In some case, the vaporized precursors can pass through a plasma generator. In one embodiment, the silicon-containing film is deposited using an ALD process. In another embodiment, the silicon-containing film is deposited using a CCVD process. In a further embodiment, the silicon-containing film is deposited using a thermal CVD process. The term “reactor” as used herein, includes without limitation, reaction chamber or deposition chamber.

In certain embodiments, the method disclosed herein avoids pre-reaction of the precursors by using ALD or CCVD methods that separate the precursors prior to and/or during the introduction to the reactor. In this connection, deposition techniques such as ALD or CCVD processes are used to deposit the silicon-containing film. In one embodiment, the film is deposited via an ALD process by exposing the substrate surface alternatively to the one or more the silicon-containing precursor, oxygen-containing source, nitrogen-containing source, or other precursor or reagent. Film growth proceeds by self-limiting control of surface reaction, the pulse length of each precursor or reagent, and the deposition temperature. However, once the surface of the substrate is saturated, the film growth ceases.

In certain embodiments, the method described herein further comprises one or more additional silicon-containing precursors other than the silazane precursor having the above Formula I. Examples of additional silicon-containing precursors include, but are not limited to, monoaminosilane (e.g., di-iso-propylaminosilane, di-sec-butylaminosilane, phenylmethylaminosilane; organo-silicon compounds such as trisilylamine (TSA); monoaminosilane (di-iso-propylaminosilane, di-sec-butylaminosilane, phenylmethylaminosilane); siloxanes (e.g., hexamethyl disiloxane (HMDSO) and dimethyl siloxane (DMSO), and hexachlorodisiloxane (HCDSO)); organosilanes (e.g., methylsilane, dimethylsilane, diethylsilane, vinyl trimethylsilane, trimethylsilane, tetramethylsilane, ethylsilane, disilylmethane, 2,4-disilapentane, 1 ,4-disilabutane, 2,5-disilahexane, 2,2-disilylpropane, 1 ,3,5-trisilacyclohexane and fluorinated derivatives of these compounds); phenyl-containing organo-silicon compounds (e.g., dimethylphenylsilane and diphenylmethylsilane); oxygen-containing organo-silicon compounds ,e.g., dimethyldimethoxysilane; 1,3,5,7-tetramethylcyclotetrasiloxane; 1,1,3,3-tetramethyldisiloxane; 1,3,5,7-tetrasila-4-oxo-heptane; 2,4,6,8-tetrasila-3,7-dioxo-nonane; 2,2-dimethyl-2,4,6,8-tetrasila-3,7-dioxo-nonane; octamethylcyclotetrasiloxane; [1,3,5,7,9]-pentamethylcyclopentasiloxane; 1,3,5,7-tetrasila-2,6-dioxo-cyclooctane; hexamethylcyclotrisiloxane; 1,3-dimethyldisiloxane; 1,3,5,7,9-pentamethylcyclopentasiloxane; hexamethoxydisiloxane, and fluorinated derivatives of these compounds.

Depending upon the deposition method, in certain embodiments, the one or more silicon-containing precursors may be introduced into the reactor at a predetermined molar volume, or from about 0.1 to about 1000 micromoles. In this or other embodiments, the silicon-containing and/or silazane precursor may be introduced into the reactor for a predetermined time period. In certain embodiments, the time period ranges from about 0.001 to about 500 seconds.

In certain embodiments, the silicon-containing films deposited using the methods described herein are formed in the presence of oxygen using an oxygen-containing source, reagent or precursor comprising oxygen. An oxygen-containing source may be introduced into the reactor in the form of at least one oxygen-containing source and/or may be present incidentally in the other precursors used in the deposition process. Suitable oxygen-containing source gases may include, for example, water (H₂O) (e.g., deionized water, purifier water, and/or distilled water), oxygen (O₂), oxygen plasma, ozone (O₃), NO, N₂O, NO₂, carbon monoxide (CO), carbon dioxide (CO₂) and combinations thereof. In certain embodiments, the oxygen-containing source comprises an oxygen-containing source gas that is introduced into the reactor at a flow rate ranging from about 1 to about 2000 square cubic centimeters (sccm) or from about 1 to about 1000 sccm. The oxygen-containing source can be introduced for a time that ranges from about 0.1 to about 100 seconds. In one particular embodiment, the oxygen-containing source comprises water having a temperature of 10° C. or greater. In embodiments wherein the film is deposited by an ALD or a cyclic CVD process, the precursor pulse can have a pulse duration that is greater than 0.01 seconds, and the oxygen-containing source can have a pulse duration that is less than 0.01 seconds, while the water pulse duration can have a pulse duration that is less than 0.01 seconds. In yet another embodiment, the purge duration between the pulses that can be as low as 0 seconds or is continuously pulsed without a purge in-between. The oxygen-containing source or reagent is provided in a molecular amount less than a 1:1 ratio to the silicon precursor, so that at least some carbon is retained in the as deposited silicon-containing film.

In certain embodiments, the silicon-containing films comprise silicon and nitrogen. In these embodiments, the silicon-containing films deposited using the methods described herein are formed in the presence of nitrogen-containing source. A nitrogen-containing source may be introduced into the reactor in the form of at least one nitrogen-containing source and/or may be present incidentally in the other precursors used in the deposition process. Suitable nitrogen-containing source gases may include, for example, ammonia, hydrazine, monoalkylhydrazine, dialkylhydrazine, nitrogen, nitrogen/hydrogen, ammonia plasma, nitrogen plasma, nitrogen/hydrogen plasma, and mixture thereof. In certain embodiments, the nitrogen-containing source comprises an ammonia plasma or hydrogen/nitrogen plasma source gas that is introduced into the reactor at a flow rate ranging from about 1 to about 2000 square cubic centimeters (sccm) or from about 1 to about 1000 sccm. The nitrogen-containing source can be introduced for a time that ranges from about 0.1 to about 100 seconds. In embodiments wherein the film is deposited by an ALD or a cyclic CVD process, the precursor pulse can have a pulse duration that is greater than 0.01 seconds, and the nitrogen-containing source can have a pulse duration that is less than 0.01 seconds, while the water pulse duration can have a pulse duration that is less than 0.01 seconds. In yet another embodiment, the purge duration between the pulses that can be as low as 0 seconds or is continuously pulsed without a purge in-between.

The deposition methods disclosed herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen-containing source, the nitrogen-containing source, and/or other precursors, source gases, and/or reagents may be performed by changing the time for supplying them to change the stoichiometric composition of the resulting silicon-containing film.

Energy is applied to the at least one of the precursor, nitrogen-containing source, reducing agent, other precursors or combination thereof to induce reaction and to form the silicon-containing film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The silazane precursors and/or other silicon-containing precursors may be delivered to the reaction chamber such as a CVD or ALD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

For those embodiments wherein the precursor(s) having Formula I is used in a composition comprising a solvent and a silazane precursor having Formula I described herein, the solvent or mixture thereof selected does not react with the silazane. The amount of solvent by weight percentage in the composition ranges from 0.5% by weight to 99.5% or from 10% by weight to 75%. In this or other embodiments, the solvent has a boiling point (b.p.) similar to the b.p. of the silazane of Formula I or the difference between the b.p. of the solvent and the b.p. of the organoaminosilane of Formula I is 40° C. or less, 30° C. or less, or 20° C. or less, or 10° C. Alternatively, the difference between the boiling points ranges from any one or more of the following end-points: 0, 10, 20, 30, or 40° C. Examples of suitable ranges of b.p. difference include without limitation, 0 to 40° C., 20 ° to 30° C., or 10 ° to 30° C. Examples of suitable solvents in the compositions include, but are not limited to, an ether (such as 1 ,4-dioxane, dibutyl ether), a tertiary amine (such as pyridine, 1-methylpiperidine, 1-ethylpiperidine, N,N′-Dimethylpiperazine, N,N,N′,N′-Tetramethylethylenediamine), a nitrile (such as benzonitrile), an alkyl hydrocarbon (such as octane, nonane, dodecane, ethylcyclohexane), an aromatic hydrocarbon (such as toluene, mesitylene), a tertiary aminoether (such as bis(2-dimethylaminoethyl) ether), or mixtures thereof.

In another embodiment, a vessel for depositing a silicon-containing film comprising one or more silazane precursor(s) having Formula I is described herein. In one particular embodiment, the vessel comprises at least one pressurizable vessel (preferably of stainless steel) fitted with the proper valves and fittings to allow the delivery of one or more precursors to the reactor for a CVD or an ALD process. In this or other embodiments, the silazane precursor having Formula I is provided in a pressurizable vessel comprised of stainless steel and the purity of the precursor is 98% by weight or greater or 99.5% or greater which is suitable for the majority of semiconductor applications. In certain embodiments, such vessels can also have means for mixing the precursors with one or more additional precursor if desired. In these or other embodiments, the contents of the vessel(s) can be premixed with an additional precursor. Alternatively, the silazane precursor and/or other precursor can be maintained in separate vessels or in a single vessel having separation means for maintaining the silazane precursor and other precursor separate during storage.

In one embodiment of the method described herein, a cyclic deposition process such as CCVD, ALD, or PEALD may be employed, wherein at least one silicon-containing precursor selected from a silazane precursor having the formula described herein and optionally a nitrogen-containing source such as, for example, ammonia, hydrazine, monoalkylhydrazine, dialkylhydrazine, nitrogen, nitrogen/hydrogen, ammonia plasma, nitrogen plasma, nitrogen/hydrogen plasma are employed.

In certain embodiments, the gas lines connecting from the precursor canisters to the reaction chamber are heated to one or more temperatures depending upon the process requirements and the container of the silazane precursor having the Formula I described herein is kept at one or more temperatures for bubbling. In other embodiments, a solution comprising the at least one silicon-containing precursor having the formula described herein is injected into a vaporizer kept at one or more temperatures for direct liquid injection.

A flow of argon and/or other gas may be employed as a carrier gas to help deliver the vapor of the at least one silazane precursor to the reaction chamber during the precursor pulsing. In certain embodiments, the reaction chamber process pressure is about 10 Torr or less. In another embodiments, the reaction chamber process pressure is about 5 Torr or less.

In a typical ALD or CCVD process, a substrate such as, without limitation, a silicon oxide, carbon doped silicon oxide, flexible substrate, or metal nitride substrate is heated on a heater stage in a reaction chamber that is exposed to the silicon-containing precursor initially to allow the silazane to chemically adsorb onto the surface of the substrate. A purge gas such as nitrogen, argon, or other inert gas purges away unabsorbed excess silazane from the process chamber. After sufficient purging, an oxygen-containing source may be introduced into reaction chamber to react with the absorbed surface followed by another gas purge to remove reaction by-products from the chamber. The process cycle can be repeated to achieve the desired film thickness. In other embodiments, pumping under vacuum can be used to remove unabsorbed excess silazane from the process chamber, after sufficient evacuation under pumping, an oxygen-containing source may be introduced into reaction chamber to react with the absorbed surface followed by another pumping down purge to remove reaction by-products from the chamber. In yet another embodiment, the silazane and the oxygen-containing source can be co-flowed into reaction chamber to react on the substrate surface to deposit silicon oxide, carbon doped silicon oxide. In a certain embodiment of cyclic CVD, the purge step is not used.

In this or other embodiments, it is understood that the steps of the methods described herein may be performed in a variety of orders, may be performed sequentially or concurrently (e.g., during at least a portion of another step), and any combination thereof. The respective step of supplying the precursors and the nitrogen-containing source gases may be performed by varying the duration of the time for supplying them to change the stoichiometric composition of the resulting silicon-containing film.

In another embodiment of the method disclosed herein, the films containing both silicon and nitrogen are formed using an ALD, PEALD, CCVD or PECCVD deposition method that comprises the steps of:
a. providing a substrate in an ALD reactor;
b. introducing into the ALD reactor at least one silazane precursor comprising only one organoamino group connected to two SiR²X₂ groups represented by the following Formula I below:

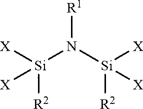

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I to chemisorb the at least one silazane precursor onto a substrate;
c. purging away any unreacted at least one silazane precursor from the reactor using a purge gas;
d. providing a nitrogen-containing source into the reactor to react with the chemisorbed at least one silazane precursor; and
e. optionally purging or pumping away any unreacted nitrogen-containing source.
Steps b to e are repeated until a desired thickness of a film containing both silicon and nitrogen is reached. In one particular embodiment of above invention, the substrate temperatures are in the range of 600° C. to 850° C., or 650° C. to 800° C., or 700° C. to 800° C. for high temperature deposition of silicon nitride or carbon doped silicon nitride. In another embodiment, the substrate temperatures are in the range of 20° C. to 500° C., or 20° C. to 400° C., or 50° C. to 400° C. for low temperature deposition of silicon nitride or carbon doped silicon nitride, especially for X=I.

In another aspect, there is provided a method of forming a film selected from a silicon oxide and a carbon doped silicon oxide film via a PEALD or a PECCVD deposition process, the method comprising the steps of:
a. providing a substrate in a reactor;
b. introducing into the reactor oxygen along with at least one silazane precursor comprising only one organoamino group connected to two SiR²X₂ groups represented by the following Formula I below:

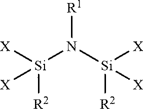

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I;
c. purging the reactor with a purge gas along with oxygen
d. introducing oxygen-containing plasma; and
e. purging the reactor with a purge gas or pumping the reactor; wherein steps b through e are repeated until a desired thickness of the film is obtained. In some embodiments of this invention, the substrate temperatures are in the range of 20° C. to 500° C., or 20° C. to 400° C., or 50° C. to 400° C. for low temperature deposition of silicon oxide.

In another embodiment of the method disclosed herein, the silicon-containing films is formed using an ALD deposition method that comprises the steps of:
a. providing a substrate in a reactor;
b. introducing into the reactor at least one silazane precursor comprising only least one silazane precursor comprising only one organoamino group connected to two SiR²X₂ groupsrepresented by the following Formula I below:

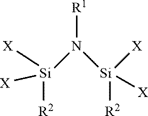

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I to chemisorbing the at least one silazane precursor onto a substrate;
c. purging away the unreacted at least one silazane precursor using a purge gas;
d. providing an oxygen-containing source to the silazane precursor onto the heated substrate to react with the chemisorbed at least one silazane precursor; and
e. optionally purging or pumping away any unreacted oxygen-containing source.

In another aspect, there is provided a method of forming a silicon nitride or silicon carbonitride film via PEALD or PECCVD process, the method comprising the steps of:
a. providing a substrate in a reactor;
b. introducing into the reactor a nitrogen-containing source and at least one silazane precursor comprising only one organoamino group connected to two SiR²X₂ groups represented by the following Formula I below:

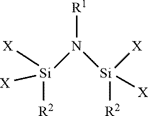

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I;
c. purging the reactor with a purge gas;
d. introducing nitrogen containing plasma ; and
e. purging the reactor with a purge gas or pumping the react; wherein steps b through e are repeated until a desired thickness of the film is obtained.
In one particular embodiment of above invention, the substrate temperatures are in the range of 20° C. to 500° C., or 20° C. to 400° C., or 50° C. to 400° C. for low temperature deposition of silicon nitride or silicon oxycarbonitride, especially for X=I.

The above steps define one cycle for the method described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the precursors and oxygen-containing source may be performed by varying the duration of the time for supplying them to change the stoichiometric composition of the resulting silicon-containing film, although always using oxygen in less than a stoichiometric amount relative to the available silicon.

For multi-component silicon-containing films, other precursors such as silicon-containing precursors, nitrogen-containing precursors, reducing agents, or other reagents can be alternately introduced into the reactor chamber.

In a further embodiment of the method described herein, the silicon-containing film is deposited using a thermal CVD process. In this embodiment, the method comprises:
a. placing one or more substrates into a reactor which is heated to one or more temperatures ranging from ambient temperature to about 1000° C.;
b. introducing at least one silazane precursor comprising only one silazane precursor comprising only least one silazane precursor comprising only one organoamino group connected to two SiR²X₂ groups represented by the following Formula I below:

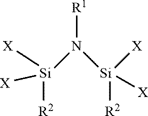

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀alkyl group, a linear or branched C₂ to C₆alkenyl group, a linear or branched C₃ to C₆alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I; and
c. providing an oxygen-containing source into the reactor to at least partially react with the at least one silazane precursor and deposit a silicon-containing film onto the one or more substrates. In certain embodiments of the CVD method, the reactor is maintained at a pressure ranging from 10 mTorr to 760 Torr during the introducing step. The above steps define one cycle for the method described herein; and the cycle can be repeated until the desired thickness of a silicon-containing film is obtained. In this or other embodiments, it is understood that the steps of the methods described herein may be performed in a variety of orders, may be performed sequentially or concurrently (e.g., during at least a portion of another step), and any combination thereof. The respective step of supplying the precursors and oxygen-containing source may be performed by varying the duration of the time for supplying them to change the stoichiometric composition of the resulting silicon-containing film, although always using oxygen in less than a stoichiometric amount relative to the available silicon.

In a further embodiment of the method described herein, an amorphous or crystalline silicon film is deposited using the Formula I precursor described herein. In this embodiment, the method comprises:
a. placing one or more substrates into a reactor which is heated to one or more temperatures ranging from ambient temperature to about 1000° C.;
b. introducing at least one silazane precursor comprising only one silazane precursor comprising only least one silazane precursor comprising only one organoamino group connected to two SiR²X₂ groupsrepresented by the following Formula I below:

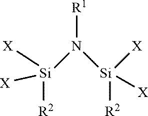

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and
c. providing a reducing agent source into the reactor to at least partially react with the at least one silazane precursor and deposit a silicon-containing film onto the one or more substratesthe reducing agent being selected from the group consisting of hydrogen, hydrogen plasma, hydrogen chloride.
In certain embodiments of the CVD method, the reactor is maintained at a pressure ranging from 10 mTorr to 760 Torr during the introducing step. The above steps define one cycle for the method described herein; and the cycle can be repeated until the desired thickness of a film is obtained.

For multi-component silicon-containing films, other precursors such as silicon-containing precursors, nitrogen-containing precursors, oxygen-containing sources, reducing agents, and/or other reagents can be alternately introduced into the reactor chamber.

In a further embodiment of the method described herein, the silicon-containing film is deposited using a thermal CVD process. In this embodiment, the method comprises:
a. placing one or more substrates into a reactor which is heated to one or more temperatures ranging from ambient temperature to about 1000° C.;
b. introducing at least one silazane precursor comprising only one organoamino group connected to two SiR²X₂ groups represented by the following Formula I below:

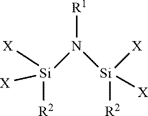

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; X is a halide selected from the group consisting of Cl, Br, and I; and d. providing a nitrogen-containing source into the reactor to at least partially react with the at least one silazane precursor and deposit a silicon-containing film onto the one or more substrates. In certain embodiments of the CVD method, the reactor is maintained at a pressure ranging from 10 mTorr to 760 Torr during the introducing step.

In a further embodiment of the method described herein, a silicon-containing film which may be amorphous or crystalline, and in one embodiment is a silicon carbonitride film, is deposited using the Formula I precursor described herein. In this embodiment, the method comprises:
a. placing one or more substrates into a reactor which is heated to one or more temperatures ranging from ambient temperature to about 1000° C.;
b. introducing at least one silazane precursor represented by the following one silazane precursor comprising only one organoamino group connected to two SiR²X₂ groups represented by the following Formula I below:

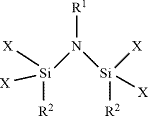

wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I;
c. purging the reactor with a purge gas;
d. providing a plasma source into the reactor to at least partially react with the at least one silazane precursor and deposit a silicon-containing film onto the one or more substrates; and
e. purging the reactor with a purge gas.

In the method described above, steps b to e define one cycle and the cycle(s) can be repeated until the desired thickness of a film is obtained. The thickness of the film ranges from about 0.1 Å to about 1000 Å, or from about 0.1 Å to about 100 Å, or from about 0.1 Å to about 10 Å. The plasma source is selected from the group consisting of: a plasma comprising hydrogen and argon, a plasma comprising hydrogen and helium, an argon plasma, a helium plasma, other noble gas(es) (e.g., neon (Ne), krypton (Kr), and xenon (Xe) plasma, and combinations thereof. In one particular embodiment of the method, the silicon-containing film comprises silicon carbonitride.

In one embodiment of the method described herein, silicon oxynitride or silicon oxycarbonitride films are deposited using a thermal ALD process. In this embodiment, the method comprises:
a. placing one or more substrates comprising a surface feature into an ALD reactor and heating to reactor to one or more temperatures ranging from about 600° C. to about 800° C. and optionally maintaining the reactor at a pressure of 100 torr or less;
b. introducing into the reactor at least one silazane selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane,1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyldisilazane, and 1,1,3,3-tetrachloro-1,3-dimethyl-2-cyclohexyldisilazane,
c. purging the reactor with an inert gas thereby removing unreacted silicon precursor and forming a composition comprising the purge gas and silicon precursor;
d. providing a nitrogen source into the reactor to react with the surface to form a silicon carbonitride films;
e. purging with inert gas to remove reaction by-products;
f. providing an oxygen-containing source into the reactor;
g. purging with inert gas to remove reaction by-products;
Steps b to g are repeated to provide a desired thickness of silicon oxynitride or silicon oxycarbonitride.

In one embodiment of the method described herein, the silicon oxide or carbon doped silicon oxide film having carbon content ranging from zero at. % to 20 at. % is deposited using a thermal ALD process and a plasma comprising hydrogen to improve film properties. In this embodiment, the method comprises:
h. placing one or more substrates comprising a surface feature into a reactor and heating to reactor to one or more temperatures ranging from ambient temperature to about 550° C. and optionally maintaining the reactor at a pressure of 100 torr or less;
i. introducing into the reactor at least one silazane selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane,1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyldisilazane, and 1,1,3,3-tetrachloro-1,3-dimethyl-2-cyclohexyldisilazane,
j. purging the reactor with an inert gas thereby removing unreacted silicon precursor and forming a composition comprising the purge gas and silicon precursor;
k. providing a nitrogen source into the reactor to react with the surface to form a silicon carbonitride films;
l. purging with inert gas to remove reaction by-products;
m. repeating steps c to f to provide a desired thickness of carbon doped silicon nitride;
n. providing post-deposition treating the carbon doped silicon nitride film with an oxygen source at one or more temperatures ranging from about ambient temperature to 1000° C. or from about 100° to 400° C. to convert the carbon doped silicon nitride film into a carbon doped silicon oxide film either in situ or in another chamber;
o. providing post-deposition exposing the carbon doped silicon oxide film to a plasma comprising hydrogen to improve film properties to improve at least one of the films’ properties; and
p. optionally post-deposition treating the carbon doped silicon oxide film with a spike anneal at temperatures from 400 to 1000C or a UV light source.
q. In this or other embodiments, the UV exposure step can be carried out either during film deposition, or once deposition has been completed.

In one embodiment, the substrate includes at least one feature wherein the feature comprises a pattern trench with aspect ratio of 1:9 or higher, opening of 180 nm or less.

In an embodiment of the method described herein, the carbon doped silicon oxide film having carbon content ranging from zero at. % to 30 at.% is deposited using a thermal ALD process and a plasma comprising hydrogen to improve film properties. In this embodiment, the method comprises:
a. placing one or more substrates comprising a surface feature into a reactor (e.g., into a conventional ALD reactor);
b. heating to reactor to one or more temperatures ranging from ambient temperature to about 550° C. and optionally maintaining the reactor at a pressure of 100 torr or less;
c. introducing into the reactor at least one silazane is selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane, 1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyldisilazane, and 1,1,3,3-tetrachloro-1,3-dimethyl-2-cyclohexyldisilazane;
d. purging the reactor with an inert gas;
e. providing a nitrogen source into the reactor to react with the surface to form a carbon doped silicon nitride film;
f. purging the reactor with inert gas to remove reaction by-products;
g. repeating steps c to f to provide a desired thickness of carbon doped silicon nitride;
h. providing post-deposition treating the carbon doped silicon nitride film with an oxygen source at one or more temperatures ranging from about ambient temperature to 1000° C. or from about 100° to 400° C. to convert the carbon doped silicon nitride film into a carbon doped silicon oxide film either in situ or in another chamber;
i. providing post-deposition exposing the carbon doped silicon oxide film to a plasma comprising hydrogen to improve at least one of the films’ physical properties; and
j. optionally post-deposition treating the carbon doped silicon oxide film with a thermal anneal at temperatures from 400 to 1000° C. or a UV light source. In this or other embodiments, the UV exposure step can be carried out either during film deposition, or once deposition has been completed.

In yet another further embodiment of the method described herein, the silicon containing film is deposited using a thermal ALD process with a catalyst comprising an ammonia or organic amine. In this embodiment, the method comprises:
a. placing one or more substrates comprising a surface feature into a reactor;
b. heating the reactor to one or more temperatures ranging from ambient temperature to about 150° C. and optionally maintaining the reactor at a pressure of 100 torr or less;
c. introducing into the reactor at least one silazane selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane,1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyldisilazane, and 1,1,3,3-tetrachloro-1,3-dimethyl-2-cyclohexyldisilazane, and a catalyst;
d. purging the reactor with an inert gas
e. providing vapors of water into the reactor to react with the precursor as well as a catalyst to form a carbon doped silicon oxide as-deposited film;
f. purging the reactor with inert gas to remove reaction by-products;
g. repeating steps c to f to provide a desired thickness of carbon doped silicon oxide;
h. providing post-deposition exposing the processed film to a plasma comprising hydrogen to improve film properties to improve at least one of the films’ properties; and
i. optionally post-deposition treating the carbon doped silicon oxide film with a spike anneal at temperatures from 400 to 1000 C or a UV light source. In this or other embodiments, the UV exposure step can be carried out either during film deposition, or once deposition has been completed.

In this or other embodiments, the catalyst is selected from a Lewis base such as pyridine, piperazine, ammonia, triethylamine or other organic amines. The amount of Lewis base vapors is at least one equivalent to the amount of the silicon precursor vapors during step c.

In an embodiment wherein the film is treated with a plasma, the plasma source is selected from the group consisting of hydrogen plasma, plasma comprising hydrogen and helium, and plasma comprising hydrogen and argon. Hydrogen plasma lowers film dielectric constant and boost the damage resistance to following plasma ashing process while still keeping the carbon content in the bulk almost unchanged.

Throughout the description, the term “ALD or ALD-like” refers to a process including, but not limited to, the following processes: a) each reactant including silicon precursor and reactive gas is introduced sequentially into a reactor such as a single wafer ALD reactor, semi-batch ALD reactor, or batch furnace ALD reactor; b) each reactant including silicon precursor and reactive gas is exposed to a substrate by moving or rotating the substrate to different sections of the reactor and each section is separated by inert gas curtain, i.e. spatial ALD reactor or roll to roll ALD reactor.

Throughout the description, the term “ashing” refers to a process to remove the photoresist or carbon hard mask in semiconductor manufacturing process using a plasma comprising oxygen source such as O₂/inert gas plasma, O₂ plasma, CO₂ plasma, CO plasma, H₂/O₂ plasma or combination thereof.

Throughout the description, the term “damage resistance” refers to film properties after oxygen ashing process. Good or high damage resistance is defined as the following film properties after oxygen ashing: film dielectric constant lower than 4.5; carbon content in the bulk (at more than 50 Å deep into film) is within 5 at. % as before ashing; Less than 50 Å of the film is damaged, observed by differences in dilute HF etch rate between films near surface (less than 50 Å deep) and bulk (more than 50 Å deep).

In certain embodiments, the silazane precursors having Formula I described herein can also be used as a dopant for metal containing films, such as but not limited to, metal oxide films or metal nitride films. In these embodiments, the metal containing film is deposited using an ALD or CVD process such as those processes described herein using metal alkoxide, metal amide, or volatile organometallic precursors. Examples of suitable metal alkoxide precursors that may be used with the method disclosed herein include, but are not limited to, group 3 to 6 metal alkoxide, group 3 to 6 metal complexes having both alkoxy and alkyl substituted cyclopentadienyl ligands, group 3 to 6 metal complexes having both alkoxy and alkyl substituted pyrrolyl ligands, group 3 to 6 metal complexes having both alkoxy and diketonate ligands; group 3 to 6 metal complexes having both alkoxy and ketoester ligands. Examples of suitable metal amide precursors that may be used with the method disclosed herein include, but are not limited to, tetrakis(dimethylamino)zirconium (TDMAZ), tetrakis(diethylamino)zirconium (TDEAZ), tetrakis(ethylmethylamino)zirconium (TEMAZ), tetrakis(dimethylamino)hafnium (TDMAH), tetrakis(diethylamino)hafnium (TDEAH), and tetrakis(ethylmethylamino)hafnium (TEMAH), tetrakis(dimethylamino)titanium (TDMAT), tetrakis(diethylamino)titanium (TDEAT), tetrakis(ethylmethylamino)titanium (TEMAT), tert-butylimino tri(diethylamino)tantalum (TBTDET), tert-butylimino tri(dimethylamino)tantalum (TBTDMT), tert-butylimino tri(ethylmethylamino)tantalum (TBTEMT), ethylimino tri(diethylamino)tantalum (EITDET), ethylimino tri(dimethylamino)tantalum (EITDMT), ethylimino tri(ethylmethylamino)tantalum (EITEMT), tert-amylimino tri(dimethylamino)tantalum (TAIMAT), tert-amylimino tri(diethylamino)tantalum, pentakis(dimethylamino)tantalum, tert-amylimino tri(ethylmethylamino)tantalum, bis(tert-butylimino)bis(dimethylamino)tungsten (BTBMW), bis(tert-butylimino)bis(diethylamino)tungsten, bis(tert-butylimino)bis(ethylmethylamino)tungsten, and combinations thereof. Examples of suitable organometallic precursors that may be used with the method disclosed herein include, but are not limited to, group 3 metal cyclopentadienyls or alkyl cyclopentadienyls. Exemplary Group 3 to 6 metal herein include, but not limited to, Y, La, Ce, Pr, Nd, Sm, Eu, Gd, Tb, Dy, Er, Yb, Lu, Ti, Hf, Zr, V, Nb, Ta, Cr, Mo, and W.

In certain embodiments, the resultant silicon-containing films or coatings can be exposed to a post-deposition treatment such as, but not limited to, a plasma treatment, chemical treatment, ultraviolet light exposure, electron beam exposure, and/or other treatments to affect one or more properties of the film.

In certain embodiments, the silicon-containing films described herein have a dielectric constant of 6 or less. In these or other embodiments, the films can a dielectric constant of about 5 or below, or about 4 or below, or about 3.5 or below. However, it is envisioned that films having other dielectric constants (e.g., higher or lower) can be formed depending upon the desired end-use of the film. An example of the silicon containing or silicon-containing film that is formed using the silazane precursors and processes described herein has the formulation SiₓO_{y}C_{z}NᵥH_{w} wherein Si ranges from about 10% to about 40%; O ranges from about 0% to about 65%; C ranges from about 0% to about 75% or from about 0% to about 50%; N ranges from about 0% to about 75% or from about 0% to 50%; and H ranges from about 0% to about 50% atomic percent weight % wherein x+y+z+v+w = 100 atomic weight percent, as determined for example, by XPS or other means. Another example of the silicon containing film that is formed using the silazane precursors and processes described herein is silicon carbonitride wherein the carbon content is from 1 at% to 80 at% measured by XPS. In yet, another example of the silicon containing film that is formed using the silazane precursors and processes described herein is amorphous silicon wherein both sum of nitrogen and carbon contents is <10 at%, preferably <5 at%, most preferably <1 at% measured by XPS.

As mentioned previously, the method described herein may be used to deposit a silicon-containing film on at least a portion of a substrate. Examples of suitable substrates include but are not limited to, silicon, germanium doped silicon, germanium, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, a flexible substrate, organic polymers, porous organic and inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

The deposited films have applications, which include, but are not limited to, computer chips, optical devices, magnetic information storages, coatings on a supporting material or substrate, microelectromechanical systems (MEMS), nanoelectromechanical systems, thin film transistor (TFT), light emitting diodes (LED), organic light emitting diodes (OLED), IGZO, and liquid crystal displays (LCD).

The following examples illustrate the method for preparing silazane precursors as well as depositing silicon-containing films described herein and are not intended to limit it in any way.

### EXAMPLES

### Example 1a. Synthesis of 1,1,1,3,3,3-Hexachloro-2-Methyldisilazane

In a 100 mL glass bottle, heptamethyldisilazane (20 g, 0.11 mol), silicon tetrachloride (155 g, 0.91 mol), and pyridine (0.45 g, 0.0057 mol) were combined and stirred at 70-80° C. for 5 days. When the mixture was analyzed by gas chromatography-mass spectrometry (GC-MS), the desired product, 1,1,1,3,3,3-hexachloro-2-methyldisilazane, was identified by the following mass peaks: m/z = 296 (M+), 261, 212, 175, 162, 135, 126, 98, 63.

### Example 1b. Alternative Synthesis of 1,1,1,3,3,3-Hexachloro-2-Methyldisilazane

To a 1 L 3-neck round-bottom flask containing a stirred mixture of 0.4 mol of silicon tetrachloride, 0.22 mol of triethylamine, and 300 mL of hexanes is added dropwise a solution of methylamine (100 mL of a 1.0 M solution in THF, 0.1 mol) at -20° C. The resulting slurry is stirred while warming to room temperature and filtered to remove the white solids. The filtrate is purified by vacuum distillation to obtain the desired product, 1,1,1,3,3,3-hexachloro-2-methyldisilazane.

### Example 2. Synthesis of 1,1,3,3-Tetrachloro-1,3-Dimethyl-2-Methyldisilazane

In a 500 mL round-bottom flask, heptamethyldisilazane (88.7 g, 0.506 mol) and trichloromethylsilane (302 g, 2.02 mol) were stirred for 1 week at room temperature. To this mixture was added an HCl solution (85 mL of 1.0 M solution in Et20, 0.085 mol) and the reaction mixture was heated to approximately 50° C. for 5 days. The translucent mixture was filtered and purified by vacuum distillation to provide 48 g of purified 1,1,3,3-tetrachloro-1,3-dimethyl-2-methyldisilazane. The boiling point was determined to be 199° C. by differential scanned calorimetry (DSC). GC-MS showed the following peaks: m/z = 256 (M+), 242, 220, 212, 204, 190, 177, 142, 126, 113, 106, 92, 79, 63.

### Example 2b. Alternative Synthesis of 1,1,3,3-Tetrachloro-1,3-Dimethyl-2-Methyldisilazane

To a 1 L 3-neck round-bottom flask containing a stirred mixture of trichloromethylsilane (0.4 mol), triethylamine (0.22 mol), and hexanes (300 mL) is added dropwise a solution of methylamine (100 mL of a 1.0 M solution in THF, 0.1 mol) at -20° C. The resulting slurry is stirred while warming to room temperature and filtered to remove the white solids. The filtrate is purified by vacuum distillation to obtain the desired product, 1,1,3,3-tetrachloro-1,3-dimethyl-2-methyldisilazane.

### Example 3. Thermal Stability of 1,1,3,3-Tetrachloro-1,3-Dimethyl-2-Methyldisilazane

Two 1 mL samples of purified 1,1,3,3-tetrachloro-1,3-dimethyl-2-methyldisilazane were heated in sealed 3.8 mL stainless steel tubes at 80° C. for 7 days. The heated samples were cooled to room temperature and analyzed by gaschromatography (GC). The assay of 1,1,3,3-tetrachloro-1,3-dimethyl-2-methyldisilazane dropped from 95.72% to an average of 95.69 %, demonstrating that 1,1,3,3-tetrachloro-1,3-dimethyl-2-methyldisilazane has excellent thermal stability and is suitable as precursor for vapor deposition processes.

### Example 3a. Synthesis of 1,1,3,3-Tetrachloro-2-Methyldisilazane

In a 500 mL round-bottom flask, heptamethyldisilazane (0.5 mol) and trichlorosilane (2 mol) are stirred for 1 week at either room temperature or elevated temperature. Optionally, pyridine or HCI (1.0 M in Et₂O) are added to the reaction mixture to facilitate complete conversion. The translucent mixture is filtered and purified by vacuum distillation to provide purified 1,1,3,3-tetrachloro-2-methyldisilazane.

### Example 3b. Alternative Synthesis of 1,1,3,3-Tetrachloro-2-Methyldisilazane

To a 1 L 3-neck round-bottom flask containing a stirred mixture of trichlorosilane (0.4 mol), triethylamine (0.22 mol), and hexanes (300 MI) iss added dropwise a solution of methylamine (100 Ml of a 1.0 M solution in THF, 0.1 mol) at -20° C. The resulting slurry is stirred while warming to room temperature and filtered to remove the white solids. The filtrate is purified by vacuum distillation to obtain the desired product, 1,1,3,3-tetrachloro-1,3-dimethyl-2-methyldisilazane.

### Example 4. Precursor Thermal Stability of 1,1,1,3,3,3-Hexachloro-2-Methyldisilazane vs 1,1,1,3,3,3-Hexachloro-Disilazane

1,1,1,3,3,3-hexachloro-disilazane and 1,1,1,3,3,3-hexachloro-2-methyldisilazane as the silazane precursors were introduced into an ALD chamber in following steps: (a) introducing the silicon precursor for 10 seconds; (b) purge with nitrogen. Steps (a) and (b) are repeated for 300 cycles. Thickness and Refractive Indices (RI) of the films were measured using a FilmTek 2000SE ellipsometer by fitting the reflection data from the film to a pre-set physical model (e.g., the Lorentz Oscillator model). Table 2 summarizes the film formed by thermal deposition of the silazane precursors at substrate temperatures of 650° C. and 700° C. respectively, demonstrating 1,1,1,3,3,3-hexachloro-2-methyldisilazane has less decomposition and thus a better precursor for high temperature ALD application.

TABLE 2

Thermal decomposition of the silazane precursors

| Silicon Precursor | Film Thickness at 650° C. (Å) | Film Thickness at 700° C. (Å) |
|---|---|---|
| 1,1,1,3,3,3-hexachloro-disilazane | 45 | 96 |
| 1,1,1,3,3,3-hexachloro-2-methyldisilazane | 27 | 36 |

### Example 5. High Temperature ALD of Silicon Nitride Using 1,1,1,3,3,3-Hexachloro-2-Methyldisilazane

1,1,1,3,3,3-hexachloro-disilazane and 1,1,1,3,3,3-hexachloro-2-methyldisilazane as the silazane precursors were introduced into an ALD chamber in following steps: (a) introducing the silicon precursor for 10 seconds; (b) purge with nitrogen; (c) introducing ammonia for 24 s; (d) purge with nitrogen. Steps (a) to (d) are repeated for many cycles to get a thicker enough film for analysis. Thickness and Refractive Indices (RI) of the films were measured using a FilmTek 2000SE ellipsometer by fitting the reflection data from the film to a pre-set physical model (e.g., the Lorentz Oscillator model). Wet etch rate was performed using 1% solution of 49% hydrofluoric (HF) acid in deionized water (about 0.5 wt. % HF). Thermal oxide wafers were used as reference for each batch to confirm solution concentration. Typical thermal oxide wafer Wet Etch Rate (WER) for 0.5 wt.% HF in deionized water solution is 0.5 Å/s. Film thickness before and after etch was used to calculate wet etch rate. The growth rate per cycles are listed in Table 3, demonstrating 1,1,1,3,3,3-hexachloro-2-methyldisilazane is suitable for ALD silicon nitride at temperature higher than 650° C. while 1,1,1,3,3,3-hexachloro-disilazane having N-H group undergoes chemical vapor deposition at 700° C., i.e. GPC is greater than 3.0 Å/cycle.

TABLE 3

Comparison of growth rate of silicon nitride using 1,1,1,3,3,3-hexachloro-2-methyldisilazane and 1,1,1,3,3,3-hexachloro-disilazane

| Silicon Precursor | GPC 650° C. (Å/cycle) | GPC 700° C. (Å/cycle) | GPC 750° C. (Å/cycle) |
|---|---|---|---|
| 1,1,1,3,3,3-hexachloro-disilazane | 2.34 | 4.48 | NA |
| 1,1,1,3,3,3-hexachloro-2-methyldisilazane | 0.42 | 1.00 | 1.50 |

### Example 6. High Temperature ALD of Silicon Oxynitride Using 1,1,1,3,3,3-Hexachloro-2-Methyldisilazane

1,1,1,3,3,3-hexachloro-2-methyldisilazane as the silazane precursors were introduced into an ALD chamber in following steps: (a) introducing the silicon precursor for 10 seconds; (b) purge with nitrogen; (c) introducing ammonia for 24 s; (d) purge with nitrogen; (e) introducing water vapors for 2 or 5 seconds; (f) purge with nitrogen;. Steps (a) to (f) are repeated for 200 cycles. The results are listed in Table 4, demonstrating 1,1,1,3,3,3-hexachloro-2-methyldisilazane is suitable for ALD silicon oxynitride at temperature higher than 700° C.

TABLE 4

Growth rate and some physical properties of the silicon oxynitride using 1,1,1,3,3,3-hexachloro-2-methyldisilazane

| Wafer temperature | NH₃ pulse (s) | Water pulse (s) | Average Rl | GPC (Å/cycle) | Relative WER |
|---|---|---|---|---|---|
| 700° C. | 24 | 5 | 1.57 | 0.87 | 1.61 |
| 700° C. | 24 | 2 | 1.71 | 0.70 | 1.42 |

1. A method for forming a silicon-containing film on at least one surface of a substrate by a deposition process selected from a chemical vapor deposition process and an atomic layer deposition process, the method comprising:
providing the at least one surface of the substrate in a reaction chamber;
introducing at least one silazane precursor represented by the following Formula I below: 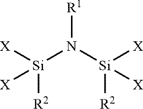
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from hydrogen, a linear or branched C₁ to C₁₀ alkyl group, a linear or branched C₂ to C₆ alkenyl group, a linear or branched C₃ to C₆ alkynyl group, a C₃ to C₁₀ cyclic alkyl group, a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I; and
introducing a nitrogen-containing source into the reactor wherein the at least one silazane precursor and the nitrogen-containing source react to form the film on the at least one surface, wherein the silazane is substantially free of organoamines, halide ions, and metal ions.

2. The method of claim 1 wherein the at least one silazane is selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane,1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3,-dimethyl-2-cyclopentyldisilazane, and 1,1,3,3-tetrachloro-1,3-dimethyl-2-cyclohexyldisilazane.

3. The method of claim 1 wherein the nitrogen-containing source is selected from the group consisting of ammonia, hydrazine, monoalkylhydrazine, dialkylhydrazine, nitrogen, nitrogen/hydrogen, ammonia plasma, nitrogen plasma, nitrogen/hydrogen plasma, and mixtures thereof.

4. The method of claim 1 wherein the silicon-containing film is selected from the group consisting of silicon nitride and silicon carbonitride.

5. A method of forming a silicon-containing film wherein the film is selected from an amorphous and a crystalline film from a deposition process selected from by plasma enhanced atomic layer deposition and plasma enhanced cyclic chemical vapor deposition, the method comprising:
placing one or more substrates into a reactor which is heated to one or more temperatures ranging from ambient temperature to about 1000° C.;
introducing at least one silazane precursor represented by the following Formula I below: 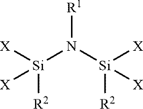
wherein R¹ is selected from the group consisting of a linear or branched C₁ to C₁₀ alkyl group, a linear or branched C₃ to C₁₀ alkenyl group, a linear or branched C₃ to C₁₀ alkynyl group, a C₃ to C₁₀ cyclic alkyl group, a C₂ to C₆ dialkylamino group, an electron withdrawing group, and a C₆ to C₁₀ aryl group; R² is selected from the group consisting of hydrogen, a linear or branched C₁ to C₁₀alkyl group, a linear or branched C₂ to C₆alkenyl group, a linear or branched C₃ to C₆ alkynyl group, a C₃ to C₁₀ cyclic alkyl group a C₂ to C₆ dialkylamino group, a C₆ to C₁₀ aryl group, a linear or branched C₁ to C₆ fluorinated alkyl group, an electron withdrawing group, a C₄ to C₁₀ aryl group, and a halide selected from the group consisting of Cl, Br, and I; and X is a halide selected from the group consisting of Cl, Br, and I, wherein the silazane is substantially free of organoamines, halide ions, metal ions;
purging the reactor with a purge gas;
providing a plasma source into the reactor to at least partially react with the at least one silazane precursor and deposit the silicon-containing film onto the one or more substrates; and
purging the reactor with a purge gas.

6. The method of claim 1 wherein the plasma source is selected from the group consisting of a plasma comprising hydrogen and argon, a plasma comprising hydrogen and helium plasma, an argon plasma, a helium plasma, and mixtures thereof.

7. The method of claim 5 wherein the at least one silazane is selected from the group consisting of 1,1,1,3,3,3-hexachloro-2-methyldisilazane, 1,1,1,3,3,3-hexachloro-2-ethyldisilazane, 1,1,1,3,3,3-hexachloro-2-n-propyldisilazane, 1,1,1,3,3,3-hexachloro-2-iso-propyldisilazane, 1,1,1,3,3,3-hexachloro-2-n-butyldisilazane, 1,1,1,3,3,3-hexachloro-2-n-propyldisilazane, 1,1,1,3,3,3-hexachloro-2-n-butyldisilazane, 1,1,1,3,3,3-hexachloro-2-iso-butyldisilazane, 1,1,1,3,3-pentachloro-2-methyldisilazane, 1,1,1,3,3-pentachloro-2-ethyldisilazane, 1,1,1,3,3-pentachloro-2-n-propyldisilazane, 1,1,1,3,3-pentachloro-2-iso-propyldisilazane, 1,1,1,3,3-pentachloro-2-methyl-3-methyl-disilazane, 1,1,1,3,3-pentachloro-2-ethyl-3-methyldisilazane, 1,1,1,3,3-pentachloro-2-n-propyl-3-methyldisilazane, 1,1,1 ,3,3-pentachloro-2-iso-propyl-3-methyldisilazane, 1,1,1,3,3,3-hexabromo-2-methyldisilazane, 1,1,1,3,3,3-bromo-2-ethyldisilazane, 1,1,1,3,3,3-bromo-2-n-propyldisilazane, 1,1,1,3,3,3-bromo-2-n-propyldisilazane, 1,1,1,3,3,3-bromo-2-n-propyldisilazane, 1,1,1,3,3,3-bromo-2-n-butyldisilazane, 1,1,1,3,3,3-bromo-2-sec-butyldisilazane 1,1,1,3,3,3-bromo-2-iso-butyldisilazane, 1,1,1,3,3,3-bromo-2-tert-butyldisilazane, 1,1,1,3,3,3-hexaiodo-2-methyldisilazane, 1,1,1,3,3,3-iodo-2-ethyldisilazane, 1,1,1,3,3,3-iodo-2-n-propyldisilazane, 1,1,1,3,3,3-iodo-2-n-butyldisilazane, 1,1,1,3,3,3-iodo-2-iso-propyldisilazane, 1,1,1,3,3,3-iodo-2-sec-butyl-disilazane, 1,1,1,3,3,3-iodo-2-tert-butyl-disilazane, 1,1,3,3-tetrachloro-1,3-dimethyl-2-methyldisilazane, 1,1,3,3-tetrachloro-1,3-dimethyl-tetrachloro-2-ethyldisilazane, 1,1,3,3-tetrachloro-1,3-dimethyl-2-n-propyldisilazane, 1,1,3,3-tetrachloro-1,3-dimethyl-2-iso-propyldisilazane, 1,1,3,3-tetrachloro-1,3-dimethyl-2-n-butyldisilazane, 1,1,3,3-tetrachloro-1,3-dimethyl-2-iso-butyldisilazane, 1,1,3,3-tetrachloro-1,3-dimethyl-2-sec-butyldisilazane, and 1,1,3,3-tetrachloro-1,3-dimethyl-2-tert-butyldisilazane, 1,1,3,3-tetrachloro-2-methyldisilazane , 1,1,3,3-tetrachloro-2-ethyldisilazane, 1,1,3,3-tetrachloro-n-propyldisilazane, 1,1,3,3-tetrachloro-2-iso-propyldisilazane, 1,1,3,3-tetrachloro-2-n-butyldisilazane,1,3,3-tetrachloro-2-iso-butyldisilazane, 1,1,3,3-tetrachloro-2-sec-butyldisilazane, 1,1,3,3-tetrachloro-2-tert-butyldisilazane, 1,1,3,3-tetrabromo-2-methyldisilazane, 1,1,3,3-tetrabromo-2-ethyldisilazane, 1,1,3,3-tetrabromo-n-propyldisilazane, 1,1,3,3-tetrabromo-2-iso-propyldisilazane, 1,1,3,3-tetrabromo-2-n-butyldisilazane, 1,1,3,3-tetrabromo-2-iso-butyldisilazane, 1,1,3,3-tetrabromo-2-sec-butyldisilazane, 1,1,3,3-tetrachloro-2-tert-butyldisilazane, 1,1,3,3-tetraiodo-2-methyldisilazane, 1,1,3,3-tetraiodo-2-ethyldisilazane, 1,1,3,3-tetraiodo-n-propyldisilazane, 1,1,3,3-tetraiodo-2-iso-propyldisilazane, 1,1,3,3-tetraiodo-2-n-butyldisilazane, 1,1,3,3-tetraiodo-2-iso-butyldisilazane, 1,1,3,3-tetraiodo-2-sec-butyldisilazane, 1,1,3,3-tetraiodo-2-tert-butyldisilazane, 1,1,3,3-tetrachloro-2-cyclopentyldisilazane, 1,1,3,3-tetrachloro-2-cyclohexyldisilazane, 1,1,3,3-tetrachloro-1,3-dimethyl-2-cyclopentyldisilazane, and 1,1,3,3-tetrachloro-1,3-dimethyl-2-cyclohexyldisilazane.
